(19) United States
(12) Patent Application Publication
(10) Pub. No.: US 2011/0056912 A1
(43) Pub. Date: Mar. 10, 2011

(54) PLASMA PROCESSING APPARATUS AND PLASMA PROCESSING METHOD

(75) Inventor: Shoichiro Matsuyama, Nirasaki (JP)

(73) Assignee: TOKYO ELECTRON LIMITED, Tokyo (JP)

(21) Appl. No.: 12/875,635

(22) Filed: Sep. 3, 2010

Related U.S. Application Data
(60) Provisional application No. 61/252,196, filed on Oct. 16, 2009.

(30) Foreign Application Priority Data
Sep. 8, 2009 (JP) 2009-206890

(51) Int. Cl. C23F 1/00; H01L 21/306; C23C 14/34; C23C 14/00; C23F 1/08; C23C 16/44; B05C 11/00; C23C 16/52

(52) U.S. Cl. 216/59; 156/345.51; 204/298.16; 204/298.37; 118/723 R; 156/345.24; 118/708; 427/571; 204/192.13; 204/192.33

(57) ABSTRACT

Uniformity in a plasma process can be increased by increasing a plasma confining effect by a cusp magnetic field over the whole circumference. There is provided a plasma processing apparatus which performs a process on a substrate by generating plasma of a processing gas in a depressurized processing chamber. The apparatus includes a magnetic field generation unit 200 including two magnet rings 210 and 220 vertically spaced from each other and arranged along a circumferential direction of the processing chamber. Each of the magnet rings includes multiple segments 212 and 222 of which magnetic poles are alternately reversed two by two along a circumferential direction of an inner surface of the magnet ring. In the magnetic field generation unit 200, arrangement of upper and lower magnetic poles is changed by rotating the lower magnet ring 220 in a circumferential direction with respect to the upper magnet ring 210.

### CROSS-REFERENCE TO RELATED APPLICATION

This application claims the benefit of Japanese Patent Application No. 2009-206890 filed on Sep. 8, 2009 and U.S. Provisional Application Ser. No. 61/252,196 filed on Oct. 16, 2009, the entire disclosures of which are incorporated herein by reference.

### FIELD OF THE INVENTION

The present disclosure relates to a plasma processing apparatus and a plasma processing method that perform a process on a substrate such as a semiconductor wafer, a FPD (Flat Panel Display) substrate, a solar cell substrate by generating plasma in a processing chamber.

### BACKGROUND OF THE INVENTION

When a plasma process such as sputtering, etching, and film formation is performed on a substrate such as a semiconductor wafer (hereinafter, simply referred to as “wafer”), there has been used a plasma processing apparatus which generates a cusp magnetic field surrounding plasma in a processing chamber in order to perform a uniform process on a process surface of the wafer.

In this plasma processing apparatus, a so-called multi-pole ring magnet in which magnets having different polarities are alternately arranged in a circumferential direction is positioned around the processing chamber, thereby generating the cusp magnetic field. Since the plasma can be confined by this cusp magnetic field, uniformity in the plasma process on the wafer can be improved.

Conventionally, it has been known that in order to improve uniformity in a process at a central portion and an edge portion of a wafer, two multi-pole ring magnets are vertically arranged and a gap therebetween is controlled or these multi-pole ring magnets are rotated (see, for example, Patent Documents 1 and 2).

Patent Document 1: Japanese Patent Laid-open Publication No. 2003-234331

Patent Document 2: Japanese Patent Laid-open Publication No. 2000-306845

Patent Document 3: Japanese Patent Laid-open Publication No. 2004-111334

However, as described in Patent Documents 1 and 2, in a plasma processing apparatus in which ring magnets are vertically arranged, depending on vertical arrangement of polarities, magnetic force lines generating a cusp magnetic field may have a region where a magnetic field perpendicular to a sidewall of the processing chamber is greater than a magnetic field parallel thereto. In this case, since a diffusion coefficient of plasma in a diametric direction (in a direction crossing the magnetic field parallel to the sidewall) cannot be reduced sufficiently, the plasma cannot be confined sufficiently. Accordingly, process uniformity in a central portion and an edge portion of a wafer may be decreased and damage to the sidewall may be caused.

Further, in Patent Document 3, it is described that two ring magnets are rotated relative to each other, but they are dipole ring magnets. In this dipole ring magnet, multiple anisotropic segment magnets are arranged in a ring shape around a processing chamber while slightly changing their magnetization directions and a uniform horizontal magnetic field is formed on the entire wafer. Here, a high frequency electric field orthogonal to a process surface of the wafer is applied and a drift motion of electrons at this time is used to perform a plasma process such as etching with very high efficiency.

In case of using the dipole ring magnet, process uniformity is highly influenced by a direction of a magnetic field formed on a wafer. Therefore, circumstances are very different from the multi-pole ring magnet in which a magnetic field is hardly formed on a wafer. For this reason, conception of the dipole ring magnet cannot be applied to the multi-pole ring magnet.

Accordingly, the present invention has been conceived in view of the foregoing problem and the present invention provides a plasma processing apparatus and a plasma processing method capable of improving uniformity in a plasma process by increasing a plasma confining effect by a cusp magnetic field in a circumferential direction.

### BRIEF SUMMARY OF THE INVENTION

In order to solve the above-mentioned problem, in accordance with one aspect of the present disclosure, there is provided a plasma processing apparatus which performs a process on a substrate by generating plasma of a processing gas in a depressurized processing chamber. The apparatus includes a mounting table provided in the processing chamber and mounting the substrate thereon; a processing gas inlet unit that introduces the processing gas into the processing chamber; a gas exhaust unit that exhausts and depressurizes an inside of the processing chamber; and a magnetic field generation unit including two magnet rings vertically spaced from each other and arranged along a circumferential direction of the processing chamber. Each of the magnet rings includes multiple segments of which magnetic poles are alternately reversed one by one or group by group along a circumferential direction of an inner surface of the magnet ring. Arrangement of upper and lower magnetic poles is changed by rotating one magnet ring in a circumferential direction with respect to the other magnet ring. Here, by way of example, the segments may be composed of permanent magnet segments or magnetic pole segments of electromagnets.

In this case, if the number of consecutively arranged segments having a same polarity is m, the one magnet ring may be rotated by 1 segment to (2m−1) segments in a circumferential direction and a plasma process may be performed on the substrate for each rotation. Then, the number of the segments in a case where the best result of the process on the substrate is obtained may be stored in a storage unit as a rotation amount. Further, before a plasma process may be performed on the substrate, the one magnet ring may be rotated as much as the number of the segments as the rotation amount in the circumferential direction with respect to the other magnet ring.

Further, the apparatus may further include a ring rotation amount adjusting mechanism that rotates the one magnet ring in the circumferential direction with respect to the other magnet ring; and a controller that controls the ring rotation amount adjusting mechanism. Here, a rotation amount may be obtained for each of processing conditions of the plasma process and the rotation amount may be stored in the storage unit in relation with each of the processing conditions. Before the plasma process is performed on the substrate based on the processing condition, the controller may read the rotation amount related to the processing condition and control the ring rotation amount adjusting mechanism based on the read rotation amount so as to adjust a rotation amount of the one magnet ring in the circumferential direction.

In this case, the apparatus may further include a ring gap adjusting mechanism that adjusts a gap between the magnet rings in a vertical direction. The storage unit may store a gap adjustment amount together with the processing condition and the rotation amount. Before the plasma process is performed on the substrate based on the processing condition, the controller may read the gap adjustment amount related to the processing condition and control the ring gap adjusting mechanism based on the read gap adjustment amount so as to adjust a gap in the vertical direction.

In order to solve the above-mentioned problem, in accordance with another aspect of the present disclosure, there is provided a plasma processing method of a plasma processing apparatus which performs a process on a substrate by generating plasma of a processing gas in a depressurized processing chamber. The plasma processing apparatus includes a mounting table provided in the processing chamber and mounting the substrate thereon; a processing gas inlet unit that introduces the processing gas into the processing chamber; a gas exhaust unit that exhausts and depressurizes an inside of the processing chamber; and a magnetic field generation unit including two magnet rings vertically spaced from each other and arranged along a circumferential direction of the processing chamber, each of the magnet rings includes multiple segments of which magnetic poles are alternately reversed one by one or group by group along a circumferential direction of an inner surface of the magnet ring; a ring rotation amount adjusting mechanism that rotates one magnet ring in a circumferential direction with respect to the other magnet ring; and a storage unit that stores a rotation amount in relation with each of processing conditions, the rotation amount being obtained for each of the processing conditions of the plasma process. The method includes before the plasma process is performed on the substrate based on each of the processing conditions, reading a rotation amount related to the processing condition; and controlling the ring rotation amount adjusting mechanism based on the read rotation amount so as to adjust a rotation amount of the one magnet ring in the circumferential direction, thereby rotating upper and lower magnetic poles as much as the rotation amount. Here, by way of example, the segments may be composed of permanent magnet segments or magnetic pole segments of electromagnets.

In this case, if the number of consecutively arranged segments having a same polarity is m, the one magnet ring may be rotated by 1 segment to (2m−1) segments in a circumferential direction and a plasma process may be performed on the substrate for each rotation. The rotation amount related to each of the processing condition may be the number of the segments in a case where the best result of the process on the substrate is obtained.

Further, the plasma processing apparatus may further include a ring gap adjusting mechanism for adjusting a gap between the magnet rings in a vertical direction. The method may further include storing a gap adjustment amount together with the processing condition and the rotation amount in the storage unit; and reading the gap adjustment amount related to the processing condition before the plasma process is performed on the substrate based on the processing condition and controlling the ring gap adjusting mechanism based on the read gap adjustment amount so as to adjust a gap in the vertical direction.

In accordance with the present disclosure, by rotating magnetic poles of lower magnet ring with respect to the upper magnet ring, a magnetic field perpendicular to a sidewall of a processing chamber can be decreased and a magnetic field parallel to the sidewall can be increased. Accordingly, it is possible to suppress diffusion of plasma over the whole circumference, and, thus, a plasma confining effect by a cusp magnetic field can be increased and uniformity in a substrate process can be improved.

### BRIEF DESCRIPTION OF THE DRAWINGS

The disclosure may best be understood by reference to the following description taken in conjunction with the following figures:

FIG. 1 is a cross sectional view showing a configuration example of a plasma processing apparatus in accordance with an embodiment of the present invention;

FIG. 2A is a perspective view showing a schematic configuration of a magnet ring in accordance with this embodiment in which there is no rotation amount in a circumferential direction;

FIG. 2B is a perspective view showing a schematic configuration of the magnet ring in this embodiment in which there is a rotation amount in a circumferential direction;

FIG. 3A is a cross sectional view for explaining a case in which a ring gap in a vertical direction is increased by a ring gap adjusting mechanism in this embodiment;

FIG. 3B is a cross sectional view for explaining a case in which a ring gap in a vertical direction is decreased by the ring gap adjusting mechanism in this embodiment;

FIG. 4 is a concept view for explaining a magnetic field formed by the magnet ring in the present embodiment;

FIG. 5 is a perspective view for explaining magnetic force lines formed by the magnet ring in the present embodiment;

FIG. 6A shows a case in which a magnetic field perpendicular to a sidewall is strong;

FIG. 6B shows a case in which a magnetic field parallel to the sidewall is strong;

FIG. 7 shows a relationship between a rotation amount and vertical arrangement of polarities;

FIG. 8 shows a relationship between a distance in a diametric direction and a magnitude |B| of a magnetic field and magnitudes |Bᵣ|, |B_{θ}|, and |B_{Z}| of its perpendicular directional components;

FIG. 9 shows a relationship between an incident angle of magnetic force lines to a sidewall of a processing chamber and a magnetic flux density;

FIG. 10 is a concept view for explaining a suppression effect of plasma diffusion by a cusp magnetic field in the present embodiment;

FIG. 11 shows a result of measuring an etching rate when a plasma etching process is performed by changing a rotation amount of the magnet ring in the present embodiment;

FIG. 12 shows a configuration example in which a magnet ring is composed of an electromagnet in the present embodiment; and

FIG. 13 shows a result of measuring an etching rate when a plasma etching process is performed by changing a rotation amount of the magnet ring illustrated in FIG. 12.

### DETAILED DESCRIPTION OF THE INVENTION

Hereinafter, embodiments of the present invention will be explained in detail with reference to accompanying drawings. Through the present specification and drawings, parts having substantially same function and configuration will be assigned same reference numerals, and redundant description will be omitted.

### (Configuration Example of a Plasma Processing Apparatus)

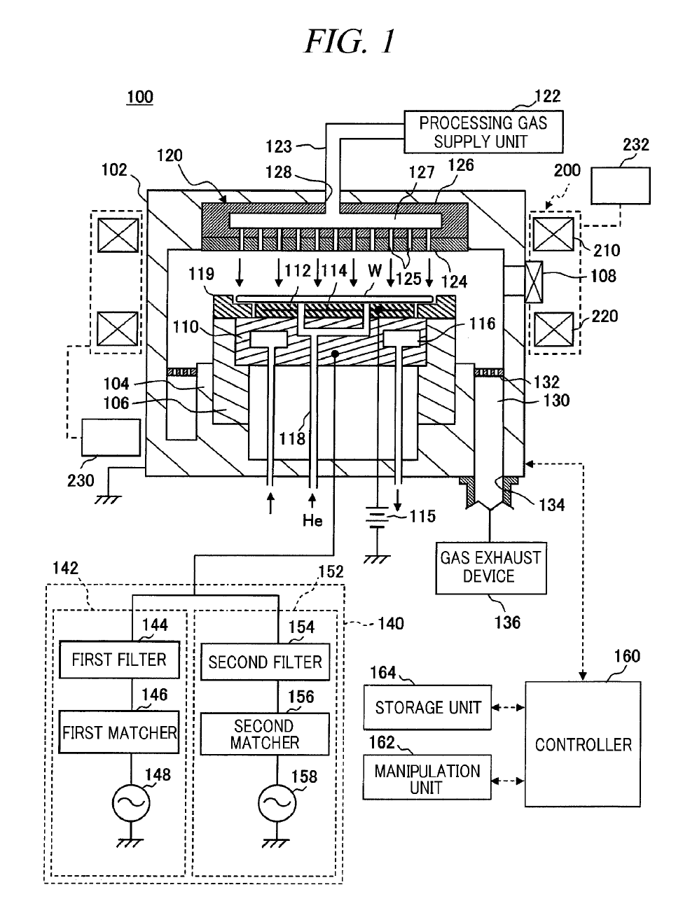

Above all, a schematic configuration of a plasma processing apparatus in accordance with an embodiment of the present invention will be explained with reference to the drawings. FIG. 1 is a cross sectional view showing a schematic configuration of a plasma processing apparatus in accordance with the present embodiment. Herein, there will be explained a plasma processing apparatus 100 configured as a capacitively coupled (parallel plate type) plasma etching apparatus in which two different high frequencies are applied to a lower electrode (a susceptor).

The plasma processing apparatus 100 includes a processing chamber 102 having a cylinder-shaped processing vessel made of metal such as aluminum or stainless steel of which a surface is anodically oxidized (alumite treated). The processing chamber 102 is grounded. In the processing chamber 102, there are provided a circular plate-shaped lower electrode (a susceptor) 110 also serving as a mounting table for mounting a substrate such as a semiconductor wafer W (hereinafter, simply referred to as “wafer”) and an upper electrode 120 also serving as a shower head configured to face the lower electrode 110 and supply a processing gas or a purge gas.

The lower electrode 110 is made of, for example, aluminum. The lower electrode 110 is held on an insulating cylindrical holder 106 on a cylindrical member 104 extended in a vertically upward direction from a bottom of the processing chamber 102. On a top surface of the lower electrode 110, an electrostatic chuck 112 for holding the wafer W by an electrostatic attracting force is installed. The electrostatic chuck 112 includes an electrostatic chuck electrode 114 made of, for example, a conductive film embedded in an insulating film. The electrostatic chuck electrode 114 is electrically connected with a DC power supply 115. With this configuration of the electrostatic chuck 112, the wafer W can be attracted to and held on the electrostatic chuck 112 by a Coulomb force caused by a DC voltage from the DC power supply 115.

Installed within the lower electrode 110 is a cooling unit. By way of example, this cooling unit is configured to circulate and supply a coolant (for example, cooling water) at a predetermined temperature to a cooling reservoir 116 extended in a circumferential direction in the lower electrode 110 from a non-illustrated chiller unit through a coolant line. A processing temperature of the wafer W on the electrostatic chuck 112 can be controlled by the coolant.

In the lower electrode 110 and the electrostatic chuck 112, a heat transfer gas supply line 118 is provided toward a rear surface of the wafer W. A heat transfer gas (a backgas) such as a He gas is introduced through the heat transfer gas supply line 118 and supplied between a top surface of the electrostatic chuck 112 and the rear surface of the wafer W. Accordingly, a heat transfer between the lower electrode 110 and the wafer W is accelerated. A focus ring 119 is installed so as to surround the wafer W mounted on the lower electrode 110. The focus ring 119 is made of, for example, quartz or silicon and installed on a top surface of the cylindrical holder 106.

The upper electrode 120 is provided at a ceiling of the processing chamber 102. The upper electrode 120 is grounded. The upper electrode 120 is connected with a processing gas supply unit 122 which supplies a gas required for a process in the processing chamber 102 via a gas line 123. By way of example, the processing gas supply unit 122 includes a gas supply source which supplies a processing gas or a purge gas required for a process performed on a wafer or a cleaning process in the processing chamber 102, a valve and a mass flow controller which control introduction of a gas from the gas supply source.

The upper electrode 120 includes an electrode plate 124 having a plurality of gas vent holes 125 at a bottom surface and an electrode support 126 which supports the electrode plate 124 detachably attached thereto. Provided within the electrode support 126 is a buffer room 127. A gas inlet 128 of this buffer room 127 is connected with the gas line 123 of the processing gas supply unit 122.

Formed between a sidewall of the processing chamber 102 and the cylindrical member 104 is a gas exhaust path 130. A ring-shaped baffle plate 132 is positioned at an entrance of the gas exhaust path 130 or on its way, and a gas exhaust port 134 is provided at a bottom portion of the gas exhaust line 130. The gas exhaust port 134 is connected with a gas exhaust device 136 via a gas exhaust pipe. The gas exhaust device 136 includes, for example, a vacuum pump and is configured to depressurize the inside of the processing chamber 102 to a certain vacuum level. Further, installed at the sidewall of the processing chamber 102 is a gate valve 108 which opens and closes a loading/unloading port for the wafer W.

The lower electrode 110 is connected with a power supply device 140 which supplies dual frequency powers thereto. The power supply device 140 includes a first high frequency power supply unit 142 which supplies a first high frequency power (high frequency power for generating plasma) of a first frequency and a second high frequency power supply unit 152 which supplies a second high frequency power (high frequency power for generating a bias voltage) of a second frequency lower than the first frequency.

The first high frequency power supply unit 142 includes a first filter 144, a first matcher 146, and a first power supply 148 connected to the lower electrode 110 in sequence. The first filter 144 prevents the second frequency power from entering into the first matcher 146. The first matcher 146 matches the first high frequency power.

The second high frequency power supply unit 152 includes a second filter 154, a second matcher 156, and a second power supply 158 connected to the lower electrode 110 in sequence. The second filter 154 prevents the first frequency power from entering into the second matcher 156. The second matcher 156 matches the second high frequency power.

A magnetic field generation unit 200 is provided so as to surround the processing chamber 102. The magnetic field generation unit 200 includes an upper magnet ring and a lower magnet ring vertically spaced from each other and arranged along a circumference of the processing chamber 102. The magnetic field generation unit 200 generates a cusp magnetic field which surrounds a plasma processing space in the processing chamber 102. One of the magnet rings 210 and 220 are configured to be rotated in a circumferential direction with respect to the other magnet ring and a vertical directional gap therebetween can be adjusted.

Herein, there will be described a case where the lower magnet ring 220 is configured to be rotatable with respect to the upper magnet ring 210 and each of the magnet rings 210 and 220 is configured to be vertically moved from a process surface of a wafer. A detailed configuration of each of the magnet rings 210 and 220 and an effect thereof will be described later. Driving mechanisms of the respective magnet rings 210 and 220 are not limited to examples to be described herein. By way of example, the upper magnet ring 210 may be configured to be rotatable with respect to the lower magnet ring 220.

The plasma processing apparatus 100 is connected with a controller (an overall control device) 160, and each component of the plasma processing apparatus 100 is controlled by this controller 160. Further, the controller 160 is connected with a manipulation unit 162 including a keyboard through which an operator inputs commands to manage the plasma processing apparatus 100 or a display which visually displays an operation status of the plasma processing apparatus 100.

Furthermore, the controller 160 is connected with a storage unit 164 that stores therein: programs for implementing various processes (e.g., a plasma process on the wafer W) performed in the plasma processing apparatus 100 under the control of the controller 160; and processing conditions (recipes) required for executing the programs.

By way of example, the storage unit 164 stores a plurality of processing conditions (recipes). Further, the storage unit 164 may store a rotation amount of each of the magnet rings 210 and 220, which will be described later, related to each of the processing conditions. Each processing condition includes a plurality of parameter values such as control parameters controlling each component of the plasma processing apparatus 100 and setting parameters. By way of example, each processing condition may include parameter values such as a flow rate ratio of processing gases, a pressure in a processing chamber, and a high frequency power value.

Moreover, the programs or processing conditions may be stored in a hard disc or a semiconductor memory, or may be set in a predetermined area of the storage unit 164 in the form of a storage medium readable by a portable computer such as a CD-ROM or a DVD.

The controller 160 reads out a program and processing condition from the storage unit 164 in response to an instruction from the manipulation unit 162 and controls each component, thereby carrying out a desired process in the plasma processing apparatus 100. Further, the processing condition can be edited by the manipulation unit 162.

### (Configuration Example of a Magnet Ring)

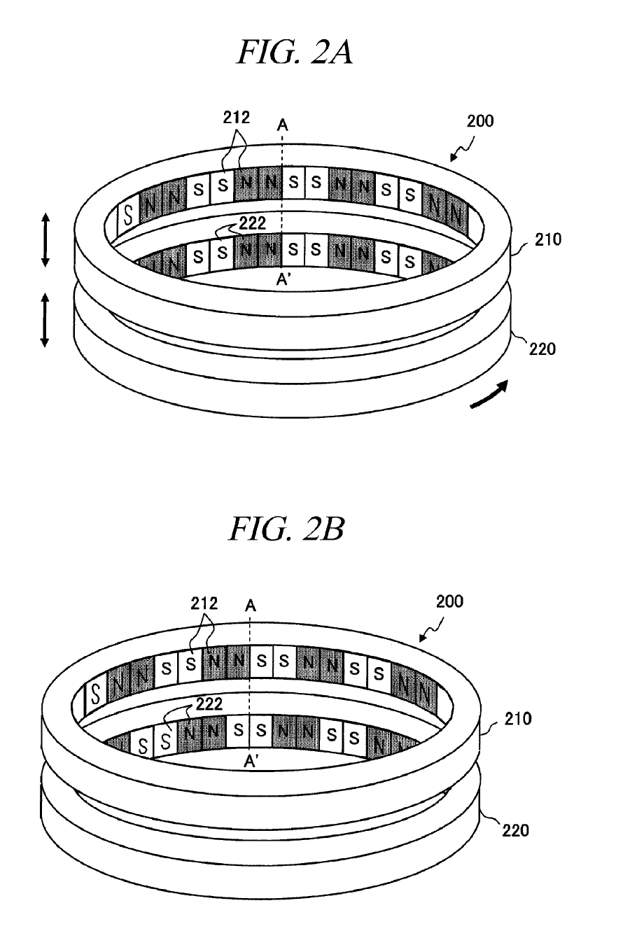

Hereinafter, a configuration example of each of the magnet rings 210 and 220 will be explained with reference to the drawings. FIGS. 2A and 2B are perspective views each showing a configuration example of the magnet rings 210 and 220. FIG. 2A shows an example where there is no rotation amount of the magnet ring 220 in a circumferential direction with respect to the magnet ring 210 and FIG. 2B shows an example where the lower magnet ring 220 is rotated by one segment in a circumferential direction with respect to the upper magnet ring 210.

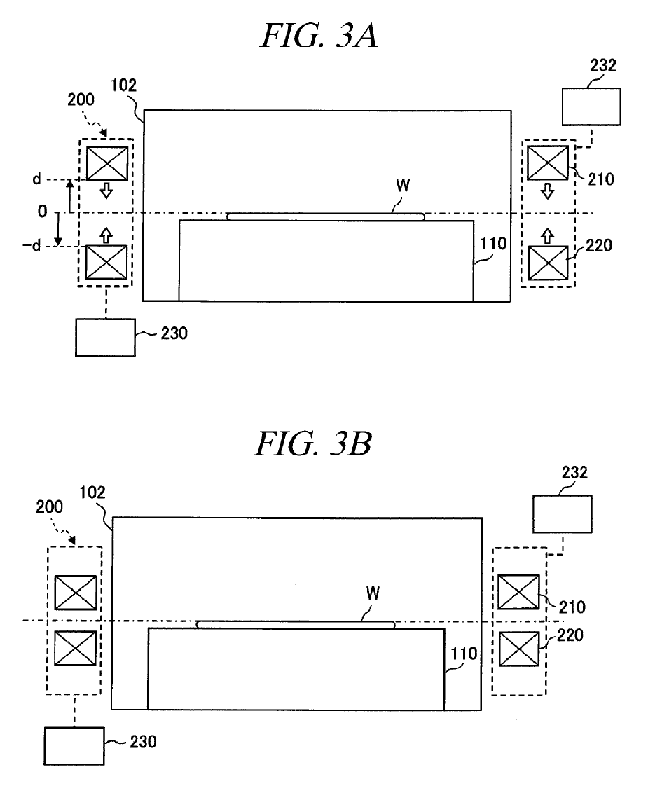

FIGS. 3A and 3B are cross sectional views for explaining a ring gap adjusting mechanism 232. FIG. 3A shows an example where a ring gap in a vertical direction is increased and FIG. 3B shows an example where a ring gap in a vertical direction is decreased. A configuration of the processing chamber 102 in FIGS. 3A and 3B is the same as that illustrated in FIG. 1, but in these drawings, the illustration of the processing chamber 102 is simplified for easy understanding of the ring gap adjusting mechanism 232.

As depicted in FIG. 2A, multiple segments 212 and 222 are arranged such that magnetic poles of each of the magnet rings 210 and 220 are placed in a ring shape (a concentric circular shape) in a circumferential direction of an inner surface (a surface facing an outer surface of a sidewall of the processing chamber 102). By way of example, each of the segments 212 and 222 may be a permanent magnet. A material of magnets constituting the segments 212 and 222 is not particularly limited and a publicly-known magnet material such as a rare earth based magnet, a ferrite magnet, and an Alnico (registered trademark) magnet may be used. A cross sectional shape of the segments 212 and 222 is not limited to a rectangular shape and may be of any shape such as a circular shape, a square shape, and a trapezoidal shape.

Hereinafter, a specific arrangement example of the segments 212 and 222 will be described in detail with reference to FIG. 2A. The segments 212 and 222 of the respective magnet rings 210 and 220 are arranged in the same manner, and, thus, there will be explained only arrangement of the upper magnet ring 210 as a representative example.

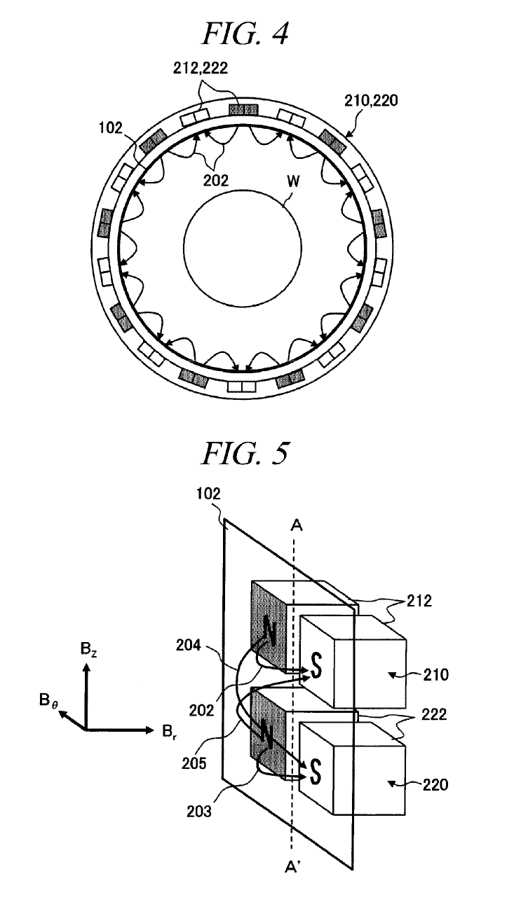

The segments 212 of the upper magnet ring 210 illustrated in FIG. 2A are arranged in a multi-pole state. That is, a plurality of segments 212 is arranged along a circumferential direction of the upper magnet ring 210 such that magnetic poles (an N-pole and an S-pole) of the segments 212 are alternately reversed group-by-group (for example, two by two). In this example, as shown in FIG. 4, eighteen poles of the segment magnets are arranged two by two.

Further, the number or arrangement of the segments 212 and 222 are not limited to the examples shown in FIGS. 2A and 4. By way of example, the number of the consecutively arranged segments 212 and 222 having the same polarity is not limited to two and may be three or more. Furthermore, the segments 212 and 222 each having the opposite polarity may be alternately arranged one by one.

As shown in FIG. 1, the magnetic field generation unit 200 includes a ring rotation amount adjusting mechanism (for example, a motor) 230 which rotates the lower magnet ring 220 by a predetermined rotation amount in a circumferential direction with respect to the upper magnet ring 210. The rotation amount may be set by a rotation angle, but herein, it is set by the number n of the rotated segments 212. By way of example, if the lower magnet ring 220 is rotated by one segment from a position illustrated in FIG. 2A, it is positioned as shown in FIG. 2B.

Further, as shown in FIG. 1, the magnetic field generation unit 200 includes a ring gap adjusting mechanism (for example, a motor) 232 which drives each of the magnet rings 210 and 220 in a vertical direction. A gap between the magnet rings 210 and 220 is decreased from a gap as shown in FIG. 3A to a gap as shown in FIG. 3B, so that a cusp magnetic field generated by the respective magnet rings 210 and 220 may become larger.

In this case, desirably, the respective magnet rings 210 and 220 are vertically equi-spaced from a surface of the wafer W. Herein, as illustrated in FIG. 3A, if a height of the process surface of the wafer W is defined as a reference height (0 mm), each of a distance d mm between the reference height and the upper magnet ring 210 and a distance −d mm between the reference height and the lower magnet ring 220 is a ring gap adjustment amount.

Hereinafter, effects of the respective magnet rings 210 and 220 and an operation of the plasma processing apparatus 100 will be explained with reference to the drawings. FIGS. 4 and 5 are concept views for explaining a magnetic field formed by each of the magnet rings 210 and 220. FIG. 4 provides a view of the magnet rings 210 and 220 when viewed from the top. FIG. 5 is a perspective view for explaining magnetic force lines formed in part of the respective rings 210 and 220. FIGS. 4 and 5 show a case where there is no rotation amount of the lower magnet ring 220 in a circumferential direction with respect to the upper magnet ring 210. Further, in FIG. 4, the segments 212 and 222 are illustrated such that two segments of the same polarity are arranged to be spaced from each other for easy understanding of the generated magnetic force lines.

When a process such as an etching process is performed on the wafer W, for example, in the processing chamber 102 by the plasma processing apparatus 100 in accordance with the present embodiment, a processing gas is supplied into the processing chamber 102 by the processing gas supply unit 122 and the processing chamber 102 is depressurized to a predetermined vacuum level by evacuating the inside by means of the gas exhaust device 136.

In this state, a first high frequency power of about 10 MHz or higher, for example, about 100 MHz is supplied to the lower electrode 110 from the first power supply 148 and a second high frequency power ranging from about 2 MHz to about 10 MHz, for example, about 3 MHz is supplied to the lower electrode 110 from the second power supply 158. Accordingly, plasma of the processing gas is generated between the lower electrode 110 and the upper electrode 120 by the first high frequency power and a self bias potential is generated in the lower electrode 110 by the second high frequency power, and, thus, a plasma process such as reactive ion etching can be performed on the wafer W. In this way, by supplying the first high frequency power and the second high frequency power to the lower electrode 110, plasma can be appropriately controlled and a satisfactory etching process can be performed.

At this time, by an operation of the respective magnet rings 210 and 220 of the magnetic field generation unit 200, as illustrated in FIG. 4, a cusp magnetic field 202 is generated at a periphery of the plasma processing space which is the inside from the sidewall of the processing chamber 102 so as to surround the plasma processing space above the wafer W. At this time, at two upper segments 212 each having the opposite polarity and two lower segments 222 each having the opposite polarity in a portion indicated by a dotted line A-A′ in FIG. 2A, magnetic force lines as shown in FIG. 5 are generated.

Between the segment 212 of an N-pole and the segment 212 of an S-pole arranged adjacently to each other, a magnetic force line 202 starting from the N-pole to the S-pole is generated. Further, between the segment 222 of an N-pole and the segment 222 of an S-pole arranged adjacently to each other, a magnetic force line 203 starting from the N-pole to the S-pole is also generated.

In each of the magnet rings 210 and 220, as shown in FIG. 2A, since two N-poles and two S-poles are alternately arranged, each of the magnetic force lines 202 and 203 is generated between them. Further, as shown in FIG. 4, the cusp magnetic field is generated at a periphery of the plasma processing space which is the inside from the sidewall of the processing chamber 102 so as to surround the plasma processing space above the wafer W.

At this time, by way of example, the cusp magnetic field ranging from about 0.02 T to about 0.2 T (i.e., from about 200 Gauss to about 2000 Gauss), desirably, from about 0.03 T to about 0.045 T (i.e., from about 300 Gauss to about 450 Gauss) is generated at the periphery of the plasma processing space, so that a substantially non-magnetic field state is formed on the wafer W. The reason why the magnitude of the magnetic field is set as stated above is that if the magnetic field is too strong, a non-magnetic field state cannot be formed on the wafer W and if the magnetic field is too weak, a plasma confining effect cannot be obtained. Here, an appropriate magnitude of the magnetic field may depend on a configuration of the apparatus, and, thus, its range may vary depending on the apparatus.

Herein, “the substantially non-magnetic field state” includes not only a state in which any magnetic field does not exist but also a state in which a magnetic field capable of affecting an etching process is not formed on the wafer W, that is, a magnetic field which substantially cannot affect a process on the wafer W exists. By way of example, desirably, a magnitude of the magnetic field on the wafer W is set in the range from about 0 T to about 0.001 T (i.e., about 10 Gauss) in order to prevent a charge-up damage to the wafer W.

As described above, by forming the cusp magnetic field at the periphery of the plasma processing space, plasma can be confined, and, thus, uniformity in an etching rate at a central portion and an edge portion of the wafer W can be improved.

However, when the cusp magnetic field is generated by the magnet rings 210 and 220 in a multi-pole state, if the vertically arranged segments have the same polarity (i.e., there is no rotation of the lower magnet ring 220 with respect to the upper magnet ring 220 in a circumferential direction) as depicted in FIG. 5, near the sidewall of the processing chamber 102, there may be a region where a diffusion coefficient of plasma in a diametric direction cannot be reduced. Here, diffusion of plasma describes a phenomenon where particles in the plasma—are spatially diffused from regions of higher density to regions of lower density to reduce non-uniformity in density and thus a group of the particles becomes easy to flow. The particles in the plasma may be active species such as electrons, ions, or radicals. Hereinafter, explanation of electrons will be provided because electrons have low mass among charged particles influenced by a magnetic field.

Generally, a diffusion coefficient Dᵥ of plasma perpendicular to a magnetic field can be expressed by the following equation (1). In the following equation (1), D denotes a diffusion coefficient of plasma parallel to a magnetic field or a non-magnetic field, ω_{c} denotes a cyclotron angular frequency, and Vm denotes a collision frequency.

Dᵥ=D/(1+(ω_{c}/Vm)²) (1)

In this case, if a magnetic field is parallel to the sidewall of the processing chamber 102, the cyclotron angular frequency ω_{c} is proportional to a magnitude of the magnetic field. Therefore, according to the equation (1), as the magnitude of the magnetic field parallel to the sidewall of the processing chamber 102 is low, the diffusion coefficient of plasma perpendicular to the magnetic field becomes closer to a diffusion coefficient in a non-magnetic field state, and as the magnitude of the magnetic field parallel to the sidewall of the processing chamber 102 is high, the diffusion coefficient of plasma perpendicular to the magnetic field becomes decreased.

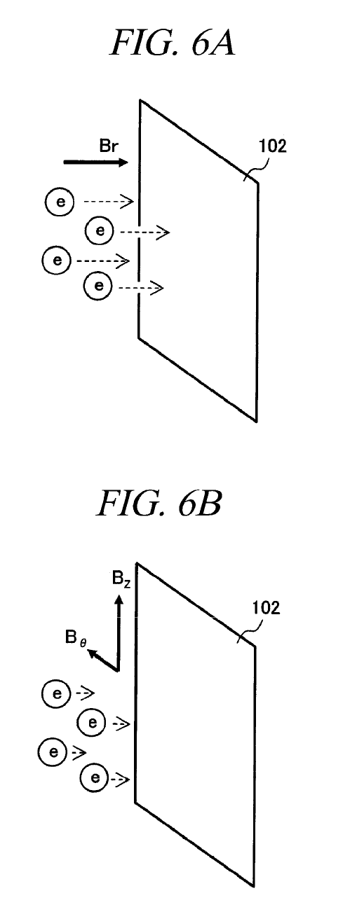

Hereinafter, there will be explained a relationship between a magnitude of a magnetic field in each direction component and movements of electrons near the sidewall of the processing chamber 102. FIGS. 6A and 6B are explanatory diagrams conceptionally showing movements of electrons near the sidewall of the processing chamber 102. FIG. 6A shows a case where a magnetic field perpendicular to the sidewall is strong, and FIG. 6B shows a case where a magnetic field parallel to the sidewall is strong.

By way of example, in the vicinity of an S-pole where a magnetic force line 202's component Br perpendicular to the sidewall of the processing chamber 102 is strong and magnetic force line 202's components B_{θ} and B_{Z} parallel to the sidewall are weak, electrons of plasma become easy to be attracted toward the sidewall as depicted in FIG. 6A, and, thus, a diffusion coefficient Dᵥ of plasma in a diametric direction (in a direction crossing a magnetic field parallel to the sidewall) is not decreased. Meanwhile, a diffusion coefficient D of plasma parallel to the magnetic field does not depend on a magnitude of the magnetic field.

When the magnet rings 210 and 220 are vertically arranged as described in the present embodiment, a magnetic force line 204 may be generated between the segment 212 and the segment 222 if there exists an opposite polarity nearby. In this case, as depicted in FIG. 5, if the vertically arranged segments have the same polarity, a Z-directional component B_{Z} of the magnetic force line 204 may be offset but a component Bᵣ perpendicular to the sidewall of the processing chamber 102 and a θ-directional component B_{θ} remain. At this time, in a region where these components Bᵣ and B_{θ} are weak, the diffusion coefficient of plasma in the diametric direction (in the direction crossing the magnetic field parallel to the sidewall) is not decreased.

If the diffusion coefficients of plasma in the diametric direction are strong over the whole area, there is a problem in that uniformity in an etching rate at a central portion and an edge portion of the wafer W may be decreased or an area facing a magnetic pole at the sidewall of the processing chamber 102 becomes easy to be eroded.

Therefore, as an examination result obtained by the present inventor, it has been found that the above-described problem can be solved by slightly rotating the lower magnet ring 220 with respect to the upper magnet ring 210 in a circumferential direction. That is, as depicted in FIG. 2B, it has been found that by changing the arrangement of the polarities of the vertically arranged segments, in the magnetic force lines generated at the segments 212 and 222, the component Bᵣ perpendicular to the sidewall of the processing chamber 102 becomes weak and the components B_{Z} and B_{θ} parallel to the sidewall become strong.

According to this result, the diffusion coefficient of plasma in the diametric direction (in the direction crossing the magnetic field parallel to the sidewall) can be decreased. That is, as depicted in FIG. 6B, the electrons in plasma become difficult to be attracted toward the sidewall, and, thus, diffusion of the plasma in the diametric direction can be suppressed. Accordingly, the uniformity in the etching rate at the central portion and the edge portion of the wafer W can be improved. Further, it may be possible to suppress erosion of the area facing the magnetic pole at the sidewall of the processing chamber 102.

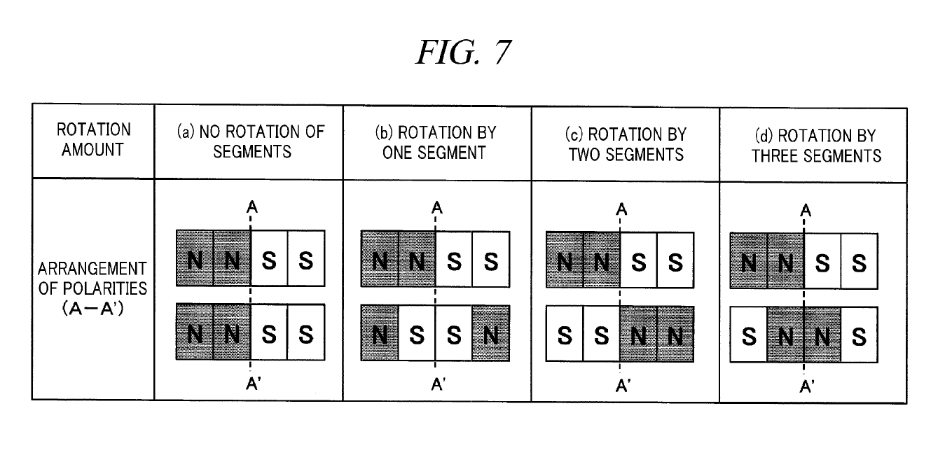

Hereinafter, referring to the drawings, there will be explained a result of an experiment for checking that if a rotation amount of the magnet ring 220 with respect to the magnet ring 210 is changed, a characteristic of magnetic force lines generated between the segments 212 and 222 is changed. FIG. 7 shows a relationship between a rotation amount of the magnet ring 220 with respect to the magnet ring 210 used in the experiment and arrangement of the segments 212 and 222.

Herein, the rotation amount of the magnet ring 220 with respect to the magnet ring 210 is expressed by the number n of segments. In a case (a) where the rotation amount is 0 (n=0), a case (b) where there is a rotation by one segment (n=1), a case (c) where there is a rotation by two segments (n=2), and a case (d) where there is a rotation by three segments (n=3), polarities of the segments 212 and 222 are arranged as shown in FIG. 7.

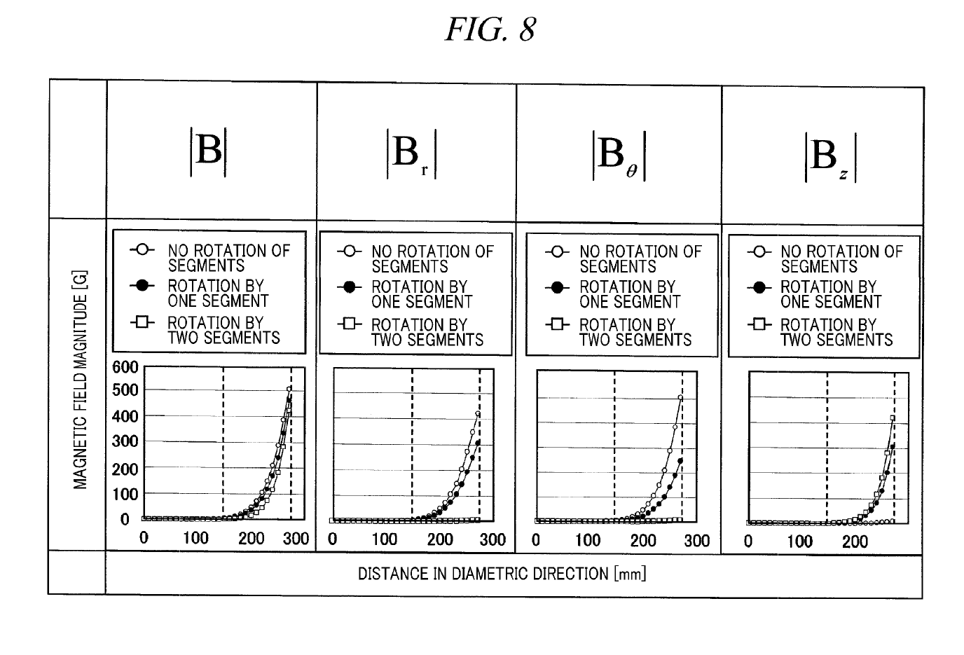

FIG. 8 shows a magnitude |B| of a cusp magnetic field and magnitudes |Bᵣ|, |B_{θ}|, and |B_{Z}| of its perpendicular directional components when the rotation amount of the magnet ring 220 with respect to the magnet ring 210 corresponds to each of the cases (a) to (c). In FIG. 8, a diameter of the wafer W is about 300 mm, and, thus, in each graph, a dotted line at a position about 150 mm away from the center of the wafer W corresponds to an edge portion of the wafer W. Since an inner diameter of the processing chamber 102 used in the experiment is about 540 mm, a dotted line at a position about 270 mm away from the center of the wafer W corresponds to an inner surface of the sidewall of the processing chamber 102. In the present embodiment, it is desirable to generate a cusp magnetic field |B| between the edge portion of the wafer W and the sidewall.

According to the experiment result in FIG. 8, it can be seen that as the rotation amount of the magnet rings 210 and 220 is increased as shown in the case where there is a rotation by one segment (n=1) and in the case where there is a rotation by two segments (n=2), the component Bᵣ perpendicular to the sidewall of the processing chamber 102 becomes decreased and the components B_{θ} and B_{Z} parallel thereto become increased in comparison with the case where the rotation amount is 0 (n=0).

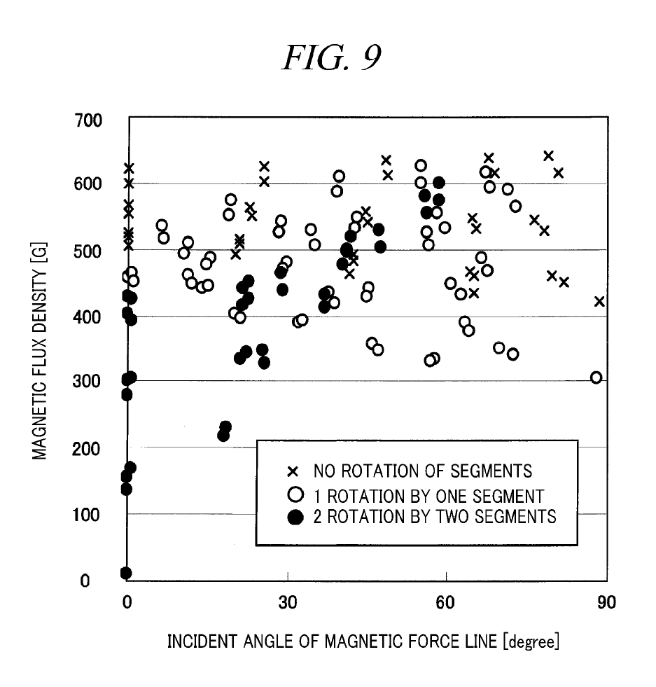

Further, FIG. 9 shows an incident angle of magnetic force lines to the sidewall of the processing chamber 102 when the rotation amount of the magnet ring 220 with respect to the magnet ring 210 corresponds to each of the cases (a) to (c). According to the experiment result in FIG. 9, it can be seen that as the rotation amount of the magnet ring 220 with respect to the magnet ring 210 is increased as shown in the case where there is a rotation by one segment (n=1) and in the case where there is a rotation by two segments (n=2), the number of magnetic force lines having an incident angle nearly perpendicular to the sidewall of the processing chamber 102 becomes decreased and the number of magnetic force lines having an incident angle nearly parallel thereto becomes increased in comparison with the case where the rotation amount is 0 (n=0).

Since the diffusion coefficient of plasma in a diametric direction can be reduced by the operation of the magnet rings 210 and 220 as described above, it is possible to suppress diffusion of the plasma in the diametric direction near the sidewall of the processing chamber 102. Accordingly, a decrease in a plasma density on the edge portion of the wafer W can be suppressed, and, thus, uniformity in a process at the central portion and the edge portion of the wafer W can be improved.

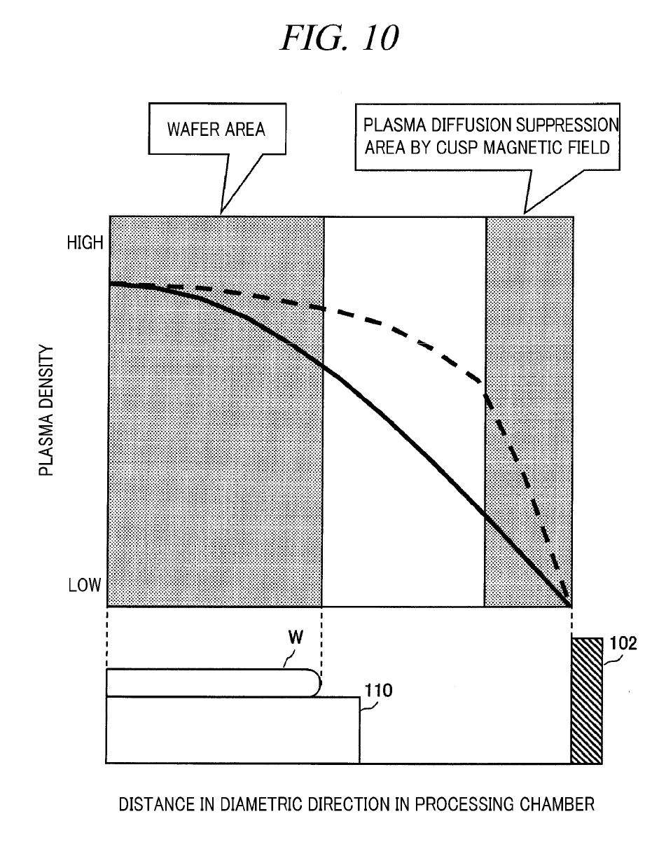

There will be given a detailed explanation thereof with reference to the drawings. A graph in FIG. 10 conceptionally shows a relationship between a distance in a diametric direction in the processing chamber 102 and a plasma density. In FIG. 10, a solid line graph represents a plasma density when there is no rotation amount of the magnet ring 220 with respect to the magnet ring 210 and a dotted line graph represents a plasma density when there is a rotation amount. As depicted in FIG. 10, if diffusion of the plasma in the diametric direction near the sidewall of the processing chamber 102 is suppressed by rotating the magnet ring 220 with respect to the magnet ring 210, the plasma density is changed from the solid line graph to the dotted line graph, and, thus, a decrease in the plasma density on the edge portion of the wafer W can be suppressed.

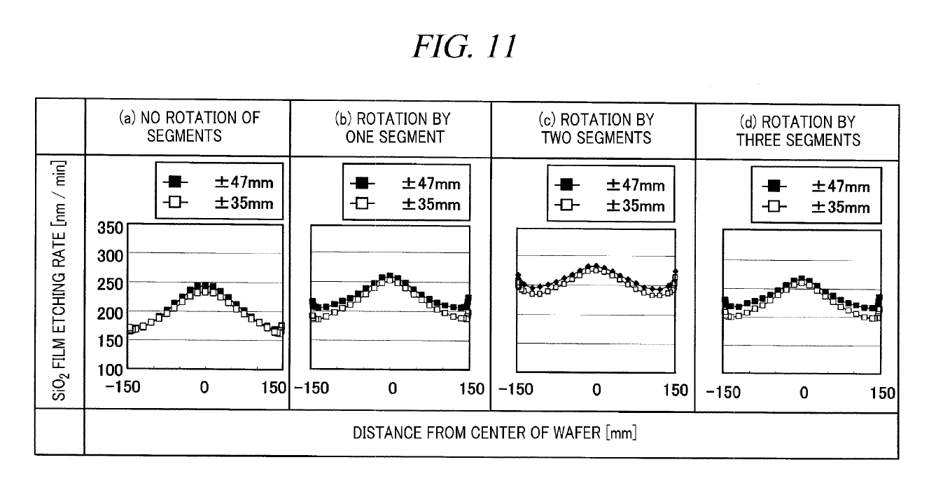

Hereinafter, referring to the drawings, there will be explained a result of an experiment in which the magnet rings 210 and 220 were rotated in a circumferential direction and an etching rate was actually measured. FIG. 11 shows a graph obtained by measuring an etching rate of a SiO₂ film when the SiO₂ film formed on the wafer W having a diameter of about 300 mm was etched in each of the cases (a) to (d) shown in FIG. 7.

As a processing condition, a pressure in the processing chamber was about 30 mTorr, a flow rate ratio of processing gases including a N₂ gas:a CH₄ gas:an O₂ gas was 60 sccm:30 sccm:10 sccm, a frequency and power of a first high frequency power were about 100 MHz and about 2400 W, respectively, and a frequency and power of a second high frequency power were about 3.2 MHz and about 200 W, respectively. Further, in order to conduct an experiment after changing a magnitude of a magnetic field, a gap between the magnet rings 210 and 220 was varied by setting d and −d indicated in FIG. 3A to be about 47 mm and about −47 mm, respectively (a magnetic field magnitude A) and to be about 35 mm and about −35 mm, respectively (a magnetic field magnitude B). In FIG. 11, the etching rate of the SiO₂ film was measured on each point of the wafer W in each of the cases (a) to (d) and plotted. Here, as the gap between the magnet rings 210 and 220 is decreased, the magnitude of the magnetic field becomes increased.

According to the experiment result as shown in FIG. 11, in case of the magnetic field magnitude A, averages of etching rates and uniformity in the surface are about 192.5 nm/min±20.9%, about 221.8 nm/min±12.3%, about 259.8 nm/min±7.7%, and about 232.2 nm/min±11.4% in the respective cases (a) to (d). In case of the magnetic field magnitude B, averages of etching rates and uniformity in the surface are about 187.8 nm/min±19.1%, about 206.6 nm/min±16.5%, about 249.2 nm/min±8.2%, and about 217.8 nm/min±14.2% in the respective cases (a) to (d).

According to this experiment result, it can be seen that in both cases of the magnetic field magnitude A and the magnetic field magnitude B, the uniformity of the etching rate in the surface is improved in the cases (b), (c), and (d) where there is a rotation amount as compared with the case (a) where a rotation amount is 0, and in the case (c) where there is a rotation by two segments (n=2), the highest uniformity in the surface can be obtained. Further, the etching rate is also improved. It is deemed as a consequence of suppression of the diffusion of plasma in the diametric direction near the sidewall of the processing chamber 102.

Moreover, in the present embodiment, there has been explained the case where the segments 212 and 222 of the respective magnet rings 210 and 220 are composed of the permanent magnets, but the present invention is not limited thereto. For example, they may be composed of magnetic pole segments of electromagnets.

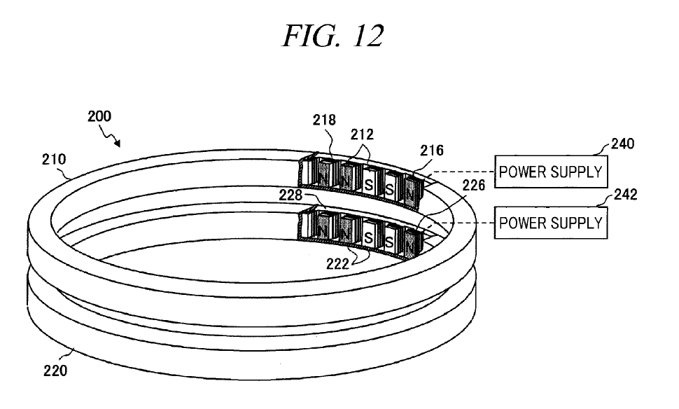

Hereinafter, there will be explained a case where the respective magnet rings 210 and 220 are composed of electromagnets with reference to FIG. 12. The magnet rings 210 and 220 in FIG. 12 are configured by winding coils 216 and 226 around ring-shaped cores 218 and 228 respectively, and covering the cores 218 and 228 with a casing. In this case, the segments 212 and 222 are composed of magnetic segments (teeth members) provided on inner surfaces of the ring-shaped cores 218 and 228.

The ring-shaped cores 218 and 228 are made of a magnetic material such as a metal-based magnet, a ferrite-based magnet, and a ceramic-based magnet. Herein, there is explained a case where the ring-shaped cores 218 and 228 are composed of ring-shaped iron cores. Further, the casing is made of, for example, ceramic or quartz so that magnetic force lines generated at the inner surfaces of the ring-shaped cores 218 and 228 can penetrate the casing. The material of the casing is not limited thereto. By way of example, only a bottom surface of the casing may be made of ceramic or quartz and the other parts thereof may be made of stainless steel. An inner surface of the casing may be opened along a circumferential direction.

The segments (teeth members) 212 and 222 are spaced apart from each other at the inner surfaces of the ring-shaped cores 218 and 228 in a circumferential direction. Formed between the respective segments 212 and 222 are groove portions, and the coils 216 and 226 are inserted into the groove portions to pass therethrough and wound around the respective segments 212 and 222.

The coils 216 and 226 are wound around the respective segments 212 and 222 along a circumferential direction of the magnet rings 210 and 220 such that magnetic poles (an N-pole and an S-pole) of the segments 212 and 222 are alternately reversed group-by-group (for example, two by two). Herein, there is explained a case where sixteen poles of the segments are arranged two by two. The coils 216 and 226 are connected with power supplies 240 and 242, respectively, for supplying currents thereto. These power supplies 240 and 242 are configured to be controlled by the controller 160.

The number or arrangement of the segments 212 and 222 are not limited to this example. By way of example, eighteen poles of the segments may be arranged as illustrated in FIG. 4. Further, the number of the consecutively arranged segments 212 and 222 having the same polarity is not limited to two and may be three or more. Furthermore, the segments 212 and 222 each having the opposite polarity may be alternately arranged one by one.

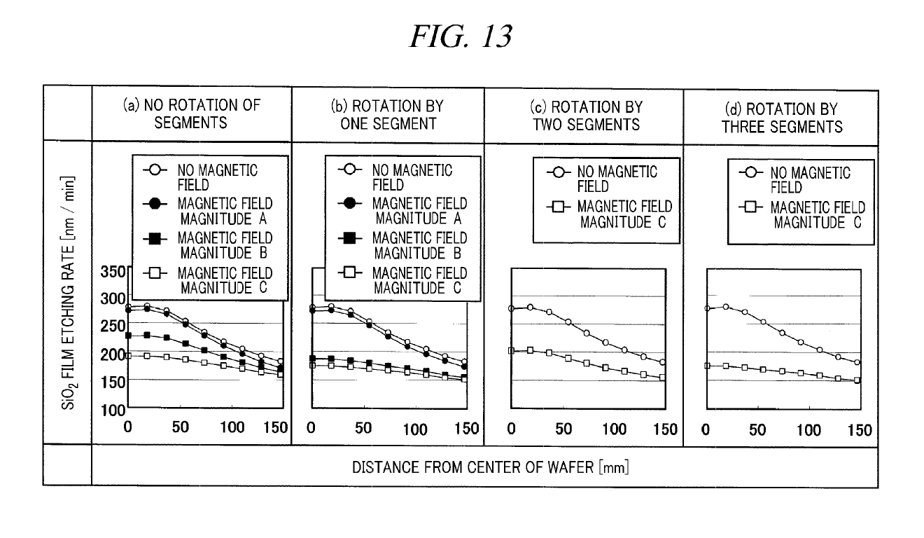

Hereinafter, there will be explained a result of an experiment in which upper and lower magnetic poles were rotated in the plasma processing apparatus 100 including the segments 212 and 222 composed of electromagnets and an etching rate was actually measured. FIG. 13 shows a graph obtained by measuring an etching rate of a SiO₂ film when the SiO₂ film formed on the wafer W having a diameter of about 300 mm was etched in each of the cases (a) to (d) shown in FIG. 7. Further, a rotation amount of the magnet rings 210 and 220 and arrangement of the segments 212 and 222 are the same as shown in FIG. 7.

As a processing condition, a pressure in the processing chamber was about 30 mTorr, a flow rate of a processing gas including a CH₄ gas was about 150 sccm, frequency and power of a first high frequency power were about 100 MHz and about 800 W, respectively, and frequency and power of a second high frequency power were about 13.56 MHz and about 200 W, respectively. Further, in order to conduct experiments while changing a magnitude of a magnetic field to be applied to the magnet rings 210 and 220, experiments under the conditions of (a) and (b) were conducted in case that currents supplied to the coils are about 0 AT (no magnetic field), about 1500 AT (a magnetic field magnitude A), about 2500 AT (a magnetic field magnitude B), and about 3000 AT (a magnetic field magnitude C). Furthermore, experiments under the conditions of (c) and (d) were conducted in case that currents are about 0 AT (no magnetic field) and about 3000 AT. This is because a tendency can be somewhat predicted by the result of the experiments under the conditions of (a) and (b).

According to the experiment result as shown in FIG. 13, in case of about 1500 AT (the magnetic field magnitude A), averages of etching rates and uniformity in the surface are about 226.8 nm/min±19.4% and about 226.8 nm/min±19.0% in the respective cases (a) and (b). In case of about 2500 AT (the magnetic field magnitude B), averages of etching rates and uniformity in the surface are about 199.9 nm/min±13.7% and about 174.0 nm/min±7.8% in the respective cases (a) and (b). Further, in case of about 3000 AT (the magnetic field magnitude C), averages of etching rates and uniformity in the surface are about 178.3 nm/min±8.9%, about 165.2 nm/min±7.2%, about 181.0 nm/min±20.6%, and about 165.2 nm/min±7.3% in the respective cases (a) to (d). Furthermore, in case of about 0 AT (no magnetic field), average of etching rates and uniformity in the surface is about 234.4 nm/min±20.6% in the cases (a) to (d).

According to this experiment result, results obtained from the cases (the magnetic field magnitudes A, B, and C) where there is a magnetic field are improved as compared to the case where there is no magnetic field. Further, it can be seen that in case of the magnetic field magnitude C, the uniformity of the etching rate in the surface is improved in the cases (b), (c), and (d) where there is a rotation amount as compared to the case (a) where a rotation amount is 0, and in the case (b) where there is a rotation by one segment (n=1), the highest uniformity in the surface can be obtained. Furthermore, the etching rate is also improved. Even in case of the magnetic field magnitudes A and B, the uniformity of the etching rate in the surface is improved in the case (b) where there is a rotation amount as compared to the case (a) where a rotation adjustment amount is 0.

According to the experiment result as shown in FIG. 11, in the case (c) where there is a rotation by two segments (n=2), the highest uniformity in the surface can be obtained. Meanwhile, according to the experiment result as shown in FIG. 13, in the case (b) where there is a rotation by one segment (n=1), the highest uniformity in the surface can be obtained. Thus, the optimum rotation amount may vary depending on a configuration of the apparatus and a processing condition. For this reason, it is desirable to determine the optimum rotation amount depending on a configuration of the apparatus and a processing condition. In this case, the optimum rotation amount depending on a processing condition may be stored in advance in the storage unit 164 in relation with a processing condition and before a plasma process is performed, the controller 160 may read the rotation amount related to this processing condition from the storage unit 164 so as to control relative positions of the magnet rings 210 and 220.

If the segments 212 and 222 are composed of electromagnets, by switching magnetic poles of segments of one magnet ring, the magnet rings 210 and 220 may be virtually moved relative to each other. Accordingly, the upper and lower magnetic poles can be changed without rotating the magnet rings.

Hereinafter, there will be explained a control method of the respective magnet rings 210 and 220 by the controller 160. Herein, as a rotation amount (the number n of segments), the optimum value pre-obtained from the experiment is used. In this case, if the number of the consecutively arranged segments 212 and 222 having the same polarity is m, there are (2m−1) ways for rotating polarities of the upper and lower segments 212 and 222. By way of example, in FIG. 7, m is 2, and, thus, the number of ways for rotating polarities of the upper and lower segments 212 and 222 is 3 ((b), (c), and (d) shown in FIG. 7). Thus, one of the magnet rings is rotated by n segments from 1 to (2m−1) in a circumferential direction and a plasma process is performed on the wafer W in each case. Then, it is desirable to store the number n of the rotated segments in the case where the best result of the process on the wafer W can be obtained in the storage unit 164 as a rotation amount. If there are multiple processing conditions, a rotation amount n is stored in relation with each processing condition. At this time, a ring gap adjustment amount (±d) is also stored in advance in the storage unit 164 in relation with each processing condition.

Before a plasma process is performed on the wafer W based on each processing condition, the controller 160 reads a rotation amount n and a ring gap adjustment amount (±d) related to the processing condition from the storage unit 164. Then, the ring gap adjusting mechanism 232 drives the magnet rings 210 and 220 vertically, thereby adjusting a gap therebetween and the ring rotation amount adjusting mechanism 230 rotates the lower magnet ring 220 so as to rotate the lower magnet ring 220 as much as the number n of segments with respect to the upper magnet ring 210. Accordingly, a rotation amount n and a ring gap adjustment amount (±d) can be automatically adjusted to have the optimum value depending on a processing condition.

Further, a rotation amount n and a ring gap adjustment amount (±d) can be flexibly preset by the operator through the operation unit 162, and the preset values are stored in the storage unit 164. Furthermore, the ring rotation amount adjusting mechanism 230 may not be provided. In this case, when the lower magnet ring 220 is positioned with respect to the upper magnet ring 210, the lower magnet ring 220 is rotated as much as a rotation amount n.

There have been explained embodiments of the present invention with reference to the accompanying drawings, but the present invention is not limited to the above-described embodiments. It would be understood by those skilled in the art that various changes and modifications may be made within the scope of the claims and their equivalents are included in the scope of the present invention.

By way of example, in the above-described embodiments, there has been explained a case where two different high frequency powers are applied only to the lower electrode 110 but the present invention is not limited thereto. The present invention can be applied to a case where high frequency powers are applied to the upper electrode 120 and the lower electrode 110 and a case where a high frequency power is applied only to the upper electrode 120. Further, there has been explained a case where the wafer W is used as a substrate and an etching process is performed thereon but the present invention is not limited thereto, and other substrates such as a FPD substrate and a solar cell substrate can be used. Furthermore, a plasma process is not limited to an etching process and other processes such as sputtering and CVD can be employed.

### INDUSTRIAL APPLICABILITY

The present invention can be applied to a plasma processing apparatus and a plasma processing method capable of performing a process on a substrate by generating plasma in a processing chamber.

What is claimed is:

1. A plasma processing apparatus which performs a process on a substrate by generating plasma of a processing gas in a depressurized processing chamber, the apparatus comprising:
a mounting table provided in the processing chamber and mounting the substrate thereon;
a processing gas inlet unit that introduces the processing gas into the processing chamber;
a gas exhaust unit that exhausts and depressurizes an inside of the processing chamber; and
a magnetic field generation unit including two magnet rings vertically spaced from each other and arranged along a circumferential direction of the processing chamber, each of the magnet rings including multiple segments of which magnetic poles are alternately reversed one by one or group by group along a circumferential direction of an inner surface of the magnet ring,
wherein arrangement of upper and lower magnetic poles is changed by rotating one magnet ring in a circumferential direction with respect to the other magnet ring.

2. The plasma processing apparatus of claim 1, wherein if the number of consecutively arranged segments having a same polarity is m, the one magnet ring is rotated by 1 segment to (2m−1) segments in a circumferential direction and a plasma process is performed on the substrate for each rotation, and then the number of the segments in a case where the best result of the process on the substrate is obtained is stored in a storage unit as a rotation amount, and before a plasma process is performed on the substrate, the one magnet ring is rotated as much as the number of the segments as the rotation amount in the circumferential direction with respect to the other magnet ring.

3. The plasma processing apparatus of claim 2, further comprising:
a ring rotation amount adjusting mechanism that rotates the one magnet ring in the circumferential direction with respect to the other magnet ring; and
a controller that controls the ring rotation amount adjusting mechanism,
wherein a rotation amount is obtained for each of processing conditions of the plasma process and the rotation amount is stored in the storage unit in relation with each of the processing conditions, and
before the plasma process is performed on the substrate based on the processing condition, the controller reads the rotation amount related to the processing condition and controls the ring rotation amount adjusting mechanism based on the read rotation amount so as to adjust a rotation amount of the one magnet ring in the circumferential direction.

4. The plasma processing apparatus of claim 3, further comprising:
a ring gap adjusting mechanism that adjusts a gap between the magnet rings in a vertical direction,
wherein the storage unit stores a gap adjustment amount together with the processing condition and the rotation amount, and
before the plasma process is performed on the substrate based on the processing condition, the controller reads the gap adjustment amount related to the processing condition and controls the ring gap adjusting mechanism based on the read gap adjustment amount so as to adjust a gap in the vertical direction.

5. The plasma processing apparatus of claim 4, wherein the segments are composed of permanent magnet segments or magnetic pole segments of electromagnets.

6. A plasma processing method of a plasma processing apparatus which performs a process on a substrate by generating plasma of a processing gas in a depressurized processing chamber,
the plasma processing apparatus including:
a mounting table provided in the processing chamber and mounting the substrate thereon,
a processing gas inlet unit that introduces the processing gas into the processing chamber,
a gas exhaust unit that exhausts and depressurizes an inside of the processing chamber,
a magnetic field generation unit including two magnet rings vertically spaced from each other and arranged along a circumferential direction of the processing chamber, each of the magnet rings including multiple segments of which magnetic poles are alternately reversed one by one or group by group along a circumferential direction of an inner surface of the magnet ring,
a ring rotation amount adjusting mechanism that rotates one magnet ring in a circumferential direction with respect to the other magnet ring, and
a storage unit that stores a rotation amount in relation with each of processing conditions, the rotation amount being obtained for each of the processing conditions of the plasma process,
the method comprising:
before the plasma process is performed on the substrate based on each of the processing conditions,
reading a rotation amount related to the processing condition; and
controlling the ring rotation amount adjusting mechanism based on the read rotation amount so as to adjust a rotation amount of the one magnet ring in the circumferential direction, thereby rotating upper and lower magnetic poles as much as the rotation amount.

7. The plasma processing method of claim 6, wherein if the number of consecutively arranged segments having a same polarity is m, the one magnet ring is rotated by 1 segment to (2m−1) segments in a circumferential direction and a plasma process is performed on the substrate for each rotation, and the rotation amount related to each of the processing condition is the number of the segments in a case where the best result of the process on the substrate is obtained.

8. The plasma processing method of claim 7, wherein the plasma processing apparatus further includes a ring gap adjusting mechanism for adjusting a gap between the magnet rings in a vertical direction, and
the method further comprises:
storing a gap adjustment amount together with the processing condition and the rotation amount in the storage unit; and
reading the gap adjustment amount related to the processing condition before the plasma process is performed on the substrate based on the processing condition and controlling the ring gap adjusting mechanism based on the read gap adjustment amount so as to adjust a gap in the vertical direction.

9. The plasma processing method of claim 8, wherein the segments are composed of permanent magnet segments or magnetic pole segments of electromagnets.
